(19) United States
(12) Patent Application Publication
(10) Pub. No.: US 2021/0109443 A1
(43) Pub. Date: Apr. 15, 2021

(54) PHOTOSENSITIVE POLYIMIDE RESIN COMPOSITION AND POLYIMIDE FILM THEREOF

(71) Applicant: MICROCOSM TECHNOLOGY CO., LTD., Tainan City (TW)

(72) Inventors: Tang Chieh Huang, Tainan City (TW); Chau Chin Chuang, Tainan City (TW); Yu Chiao Shih, Tainan City (TW); Kun Han Hsieh, Tainan City (TW)

(73) Assignee: MICROCOSM TECHNOLOGY CO., LTD., Tainan City (TW)

(21) Appl. No.: 16/970,557

(22) PCT Filed: Jan. 23, 2019
(86) PCT No.: PCT/CN2019/072781

§ 371 Date: Aug. 17, 2020

(51) Int. Cl. G03F 7/028; C08G 73/14; C08K 3/013; C08K 3/04; C08K 3/22; C08K 3/34; C08K 3/36

(52) U.S. Cl. CPC G03F 7/028; C08G 73/14; C08K 3/013; B82Y 30/00; C08K 3/22; C08K 3/346; C08K 3/36; C08K 3/042

(57) ABSTRACT

The present invention provides a photosensitive polyimide resin composition, which comprises (a) a photosensitive polyimide represented by formula (1); (b) a filler selected from one or more of alumina, graphene, inorganic clay, silica, and zinc oxide and having a particle diameter ranging from 10 nm to 1.0 μm; (c) a photo radical initiator; (d) a radical polymerizable compound; and (e) a solvent for dissolving the photosensitive polyimide;

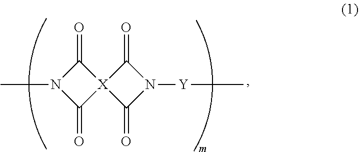

wherein X is derived from a tetracarboxylic dianhydride, Y is derived from a diamine, and m is a positive integer from 1 to 5000.

### BACKGROUND OF THE INVENTION

### Field of the Invention

The present invention relates to a photosensitive resin composition and, in particular, to a photosensitive resin composition having a photosensitive polyimide as the main component.

### Description of the Prior Art

Generally, polyimide resin is prepared by the condensation polymerization of aromatic tetracarboxylic acid or its derivatives, aromatic diamine, and aromatic diisocyanate. The prepared polyimide resin has excellent heat resistance, chemical resistance, and mechanical and electrical properties, so it is widely used in the field of electronics, for example, as semiconductor encapsulants.

In the manufacturing process of semiconductor device that utilize polyimide, it is often necessary to use Micro Lithography to make circuit patterns. If a conventional non-photosensitive polyimide is used, an additional photoresist layer must be applied for patterning and removed by etching process after. Therefore, a photosensitive polyimide (PSPI) can simplify the process for it has both the characteristics of photoresistance and the ability to serve as an insulating protective material. These novel characters make considerable progress in the process of flexible printed circuit (FPC) and make PSPI a very popular and advanced material.

However, the photosensitive polyimide has a relatively low transmittance in the visible light region and a color of yellow or brown, which limit the application of this novel material as a transparent protective layer or an insulating layer in a liquid crystal display device.

### SUMMARY OF THE INVENTION

Accordingly, the aim of the present invention is to provide a photosensitive polyimine resin composition capable of forming a film with low yellowness and high transmittance.

To achieve the above objective, the present invention provides a photosensitive polyimide resin composition, which comprises (a) a photosensitive polyimide represented by formula (1); (b) a filler selected from one or more of alumina, graphene, inorganic clay, silica, and zinc oxide and having a particle diameter ranging from 10 nm to 1.0 μm; (c) a photo radical initiator; (d) a radical polymerizable compound; and (e) a solvent for dissolving the photosensitive polyimide;

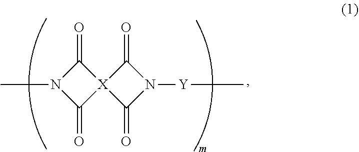

wherein X is derived from a tetracarboxylic dianhydride, Y is derived from a diamine, and m is a positive integer from 1 to 5000.

Preferably, the tetracarboxylic dianhydride is 3,3′,4,4′-biphenyltetracarboxylic dianhydride, 3,3′,4,4′-benzophenone tetracarboxylicdianhydride, 4,4′-oxydiphthalic anhydride, bis(3,4-dicarboxyphenyl)methane dianhydride, 2,2-di(3,4-dicarboxyphenyl)propane dianhydride, 2,2-bis(3,4-dicarboxyphenyl)propane dianhydride, 1,3-bis(3,4-dicarboxyphenoxy)benzenedianhydride, 1,4-bis(3,4-dicarboxyphenoxy)benzene anhydride, 4,4′-bis(3,4-dicarboxyphenoxy)biphenyl dianhydride, 2,2-bis[4-(3,4-dicarboxyphenoxy)phenyl]propane dianhydride, ethylene glycol bis(trimellitic anhydride) (TMEG), propylene glycol bis(trimellitic anhydride) (TMPG), 1,2-propanediol bis(trimellitic anhydride), butanediolbis(trimellitic anhydride), 2-methyl-1,3-propanediol bis(trimellitic anhydride), dipropylene glycol bis(trimellitic anhydride), 2-methyl-2,4-pentanediol bis(trimellitic anhydride), diethylene glycol bis(trimellitic anhydride), tetraethylene glycol bis(trimellitic anhydride), hexaethylene glycol bis(trimellitic anhydride), neopentyl glycol bis(trimellitic anhydride), hydroquinone bis(2-hydroxyethyl)ether bis(trimellitic anhydride), 2-phenyl-5-(2,4-xylyl)-1,4-hydroquinone bis(trimellitic anhydride), 2,3-dicyanohydroquinone cyclobutane-1,2,3,4-tetracarboxylic dianhydride, 1,2,3,4-cyclopentanetetracarboxylic dianhydride, 1,2,4,5-cyclohexane tetracarboxylicdianhydride, bicyclo[2.2.1]heptane-2,3,5,6-tetracarboxylic dianhydride, bicyclo[2.2.2]oct-7-ene-2,3,5,6-tetracarboxylic dianhydride, bicyclo[2.2.2]octane-2,3,5,6-tetracarboxylic dianhydride, 2,3,5-tricarboxy-cyclopentyl acetic dianhydride, bicyclo[2.2.1]heptane-2,3,5-tricarboxy-6-acetic dianhydride, decahydro-1,4,5,8-dimethanonaphthalene-2,3,6,7-tetracarboxylic dianhydride, butane-1,2,3,4-tetracarboxylic dianhydride, 3,3′,4,4′-dicyclohexyltetracarboxylic dianhydride, or a combination of two or more thereof.

Preferably, the diamine is 3,3′-diaminodiphenyl sulfone, 4,4′-diaminodiphenyl sulfone, 3,3′-methylenediphenylamine, 4,4′-methylenediphenylamine, 2,2-bis(4-aminophenyl)propane, 2,2-bis(4-aminophenyl)hexafluoropropane, 2,2′-bis(trifluoromethyl)benzidine, 2,2′-dimethylbenzidine, 3,3′-dihydroxybenzidine, 1,3-bis(3-aminophenoxy)benzene, 1,3-bis(4-aminophenoxy)benzene, 1,4-bis(4-aminophenoxy)benzene, 4,4′-bis(4-aminophenoxy)biphenyl, 2,2-bis[4-(4-aminophenoxy)phenyl]propane, 2,2-bis[4-(4-aminophenoxy)phenyl]-1,1,1,3,3,3-hexafluoropropane, 1,3-bis[4-(3-aminophenoxy)benzoyl]benzene, 4,4′-diaminobenzanilide, 2,2-bis(3-amino-4-hydroxyphenyl)hexafluoropropane, 5-amino-2-(p-aminophenyl)benzoxazole, 6-amino-2-(p-aminophenyl)benzoxazole, or a combination of two or more thereof.

Preferably, the particle diameter of the filler ranges from 20 nm to 0.2 μm.

Preferably, the filler accounts for 10% to 50% by weight of a solid content of the photosensitive polyimide resin composition. More preferably, the filler accounts for 20% to 40% by weight of a solid content of the photosensitive polyimide resin composition.

Preferably, the radical polymerizable compound is a compound having at least two (meth)acrylate groups.

Preferably, the radical polymerizable compound is a polyamic acid ester having the (meth)acrylate group. More preferably, a content of the polyamic acid ester having the (meth)acrylate group in the radical polymerizable compound is from 10% to 98% by weight.

Preferably, a polyimide film formed from the resin composition has a total light transmittance over 90% at the range from 400 to 700 nm and a yellowness of less than 2.

The present invention also provides a polyimide film formed from the resin composition described above.

Preferably, the polyimide film has a total light transmittance over 90% at the range from 400 to 700 nm and a yellowness less than 2.

Preferably, the polyimide film has a transmittance over 85% at the range from 400 to 700 nm after a thermal-resistant test at 260° C. for 10 minutes and a ΔE less than 2.0.

The present invention also provides a substrate comprising the polyimide film described above.

The photosensitive polyimide resin composition of the present invention composes specific components, and can form a polyimide film having the characteristics of low yellowness and high transmittance by adding the specific filler with a particle diameter between 10 nm to 1.0 μm.

### DETAILED DESCRIPTION OF THE EMBODIMENTS

The present invention provides a photosensitive polyimide resin composition, which comprises (a) a photosensitive polyimide represented by formula (1); (b) a filler selected from one or more of alumina, graphene, inorganic clay, silica, aluminum oxide, and zinc oxide and having a particle diameter ranging from 10 nm to 1.0 μm, preferably 20 nm to 0.2 μm; (c) a photo radical initiator; (d) a radical polymerizable compound; and (e) a solvent for dissolving the photosensitive polyimide;

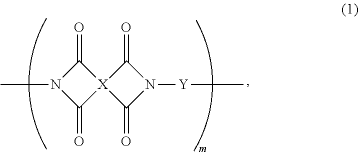

wherein X is derived from a tetracarboxylic dianhydride, Y is derived from a diamine, and m is a positive integer from 1 to 5000, such as 500, 1000, 1500, 2000, 2500, 3000, 3500, 4000, or 4500. In some embodiments, m is between any two of the above values.

The photosensitive polyimide of the present invention is a solvent-soluble polyimide, which is prepared by the chemical cyclodehydration or thermal cyclodehydration of a diamine and a tetracarboxylic dianhydride. More specifically, the diamine and the tetracarboxylic dianhydride are usually dissolved in an organic solvent, and the resulting solution is stirred under controlled temperature conditions until the polymerization of tetracarboxylic dianhydride and diamine is completed, obtaining a polyimide precursor (i.e. polyamic acid). The concentration of the obtained polyamic acid solution is usually ranged from 5 to 35 wt %, and the concentration is more preferably ranged from 10 to 30 wt %. When the concentration is within the region as mentioned, an appropriate molecular weight and solution viscosity can be obtained. In the present invention, the polymerization method of the polyimide is not particularly limited. Also, the order of addition of tetracarboxylic dianhydride monomers and diamine monomers, the combination of the monomers, and the adding amount thereof are not particularly limited. For example, the polyimide of the present invention can undergo random or sequential polymerization of block components by conventional polymerization methods.

The preparation method for the polyimide by cyclodehydration of the polyimide precursor (polyamic acid) is not particularly limited. More specifically, it can use the chemically cyclodehydration method by adding pyridine, triethylamine, or N,N-diisopropylethylamine that are optionally acting as an alkaline reagent and acetic anhydride serving as a dehydration agent into the polyamic acid under nitrogen or oxygen atmosphere. After the reaction is completed, the resulting colloid is washed by water and filtered to obtain the polyimide powder. Alternatively, the thermal cyclodehydration method may be used adding an azeotropic reagent (such as, but not limited to, toluene or xylene) into the polyamic acid, than raises the temperature up to 180° C. to remove the water produced from the cyclodehydration of the polyamic acid and the azeotropic reagent. After the reaction is completed, the solvent-soluble polyimide can be obtained. While preparing the solvent-soluble polyimide, other reagents which enhance the reaction efficiency may be added, such as, but not limited to, a catalyst, an inhibitor, an azeotropic agent, a leveling agent, or a combination thereof.

The photosensitive polyimide of the present invention is obtained by polymerizing a tetracarboxylic dianhydride with a diamine. In other words, X is a tetravalent organic group derived from the tetracarboxylic dianhydride, and Y is a divalent organic group derived from the diamine

Examples of the tetracarboxylic dianhydride include, but are not limited to, 3,3′,4,4′-biphenyltetracarboxylic dianhydride, 3,3′,4,4′-benzophenone tetracarboxylicdianhydride, 4,4′-oxydiphthalic anhydride, bis(3,4-dicarboxyphenyl)methane dianhydride, 2,2-di(3,4-dicarboxyphenyl)propane dianhydride, 2,2-bis(3,4-dicarboxyphenyl)propane dianhydride, 1,3-bis(3,4-dicarboxyphenoxy)benzenedianhydride, 1,4-bis(3,4-dicarboxyphenoxy)benzenedianhydride, 4,4′-bis(3,4-dicarboxyphenoxy)biphenyl dianhydride, 2,2-bis[4-(3,4-dicarboxyphenoxy)phenyl]propane dianhydride, ethylene glycol bis(trimellitic anhydride) (TMEG), propylene glycol bis(trimellitic anhydride) (TMPG), 1,2-propanediol bis(trimellitic anhydride), butanediolbis(trimellitic anhydride), 2-methyl-1,3-propanediol bis(trimellitic anhydride), dipropylene glycol bis(trimellitic anhydride), 2-methyl-2,4-pentanediol bis(trimellitic anhydride), diethylene glycol bis(trimellitic anhydride), tetraethylene glycol bis(trimellitic anhydride), hexaethylene glycol bis(trimellitic anhydride), neopentyl glycol bis(trimellitic anhydride), hydroquinone bis(2-hydroxyethyl)ether bis(trimellitic anhydride), 2-phenyl-5-(2,4-xylyl)-1,4-hydroquinone bis(trimellitic anhydride), 2,3-dicyanohydroquinone cyclobutane-1,2,3,4-tetracarboxylic dianhydride, 1,2,3,4-cyclopentanetetracarboxylic dianhydride, 1,2,4,5-cyclohexane tetracarboxylicdianhydride, bicyclo[2.2.1]heptane-2,3,5,6-tetracarboxylic dianhydride, bicyclo[2.2.2]oct-7-ene-2,3,5,6-tetracarboxylic dianhydride, bicyclo[2.2.2]octane-2,3,5,6-tetracarboxylic dianhydride, 2,3,5-tricarboxy-cyclopentyl acetic dianhydride, bicyclo[2.2.1]heptane-2,3,5-tricarboxy-6-acetic dianhydride, decahydro-1,4,5,8-dimethanonaphthalene-2,3,6,7-tetracarboxylic dianhydride, butane-1,2,3,4-tetracarboxylic dianhydride, and 3,3′,4,4′-dicyclohexyltetracarboxylic dianhydride. These tetracarboxylic dianhydrides may be used singly or in combination of two or more (such as three, four, five) thereof.

Examples of the diamine include, but are not limited to, 3,3′-diaminodiphenyl sulfone, 4,4′-diaminodiphenyl sulfone, 3,3′-methylenediphenylamine, 4,4′-methylenediphenylamine, 2,2-bis(4-aminophenyl)propane, 2,2-bis(4-aminophenyl)hexafluoropropane, 2,2′-bis(trifluoromethyl)benzidine, 2,2′-dimethylbenzidine, 3,3′-dihydroxybenzidine, 1,3-bis(3-aminophenoxy)benzene, 1,3-bis(4-aminophenoxy)benzene, 1,4-bis(4-aminophenoxy)benzene, 4,4′-bis(4-aminophenoxy)biphenyl, 2,2-bis[4-(4-aminophenoxy)phenyl]propane, 2,2-bis[4-(4-aminophenoxy)phenyl]-1,1,1,3,3,3-hexafluoropropane, 1,3-bis[4-(3-aminophenoxy)benzoyl]benzene, 4,4′-diaminobenzanilide, 2,2-bis(3-amino-4-hydroxyphenyl)hexafluoropropane, 5-amino-2-(p-aminophenyl)benzoxazole, 6-amino-2-(p-aminophenyl)benzoxazole, and the like. These diamines may be used singly or in combination of two or more (such as three, four, five) thereof.

In the present invention, in consideration of other characteristics, such as pattern formability, the amount of filler is preferably ranged from 10 to 50 wt %, more preferably ranged 20 to 40 wt %, of a solid content of the photosensitive polyimide resin composition.

The photo radical initiator is an initiator commonly used in photosensitive resin composition. Examples of the photo radical initiator may include, but are not limited to, an oxime compound such as oxime derivatives, a ketone compound (including acetophenones, benzophenones, and thioxanthone compounds), a triazine compound, a benzoin compound, a metallocene compound, a triazine compound, or an acylphosphine compound. These photo initiators may be used singly or in combination of two or more (such as three, four, five) thereof. From the viewpoint of exposure sensitivity, the photo radical initiator is preferably an acylphosphine compound or an oxime compound.

Examples of the oxime compound such as oxime derivatives may include, but are not limited to, O-acyloxime-based compounds, 2-(O-benzoyloxime)-1-[4-(phenylthio)phenyl]-1,2-octanedione, 1-(O-acetyloxime)-1-[9-ethyl-6-(2-methylbenzoyl)-9H-carbazol-3-yl] ethyl ketone, O-ethoxycarbonyl-α-oxyamino-1-phenylpropan-1-one, and the like. These compounds may be used singly or in combination of two or more (such as three, four, five) thereof. Examples of the O-acyloxime-based compound may include, but are not limited to, 1,2-octanedione, 2-dimethylamino-2-(4-methylbenzyl)-1-(4-morpholine-4-yl-phenyl)-butan-1-one, 1-(4-phenylsulfanylphenyl)-butane-1,2-dione-2-oxime-O-benzoate, 1-(4-phenylsulfanylphenyl)-octane-1,2-dione-2-oxime-O-benzoate, 1-(4-phenylsulfanylphenyl)-octan-1-oxime-O-acetate, 1-(4-phenylsulfanylphenyl)-butan-1-oxime-O-acetate, and the like. Those O-acyloxime compounds may be used singly or in combination of two or more (such as three, four, five) thereof. Examples of the acylphosphine compound comprise bis(2,4,6-trimethylbenzoyl)phenylphosphine oxide or 2,4,6-trimethylbenzoyl-diphenyloxophosphine, but are not limited thereto. Those acylphosphine compounds may be used singly or in combination of two or more thereof.

In the present invention, the content of the photo radical initiator is preferably between 0.1 to 20 wt %, more preferably between 1 to 10 wt %, based on that of the main resin. When the content of the photo radical initiator is within the range mentioned above, the polyimide film can be ensured to have excellent reliability, because the polyimide is sufficiently cured while exposured to light during pattern formation.

Photo radical initiators can combine with photosensitizers, which is capable of transferring the energy absorbed from light and stored it as chemical energy. Examples of the photosensitizer may include, but are not limited to, tetraethylene glycol bis-3-mercaptopropionate, pentaerythritoltetrakis-mercaptopropionate, dipentaerythritol tetraalkyl-3-mercaptopropionate, and the like. These photosensitizers may be used singly or in combination of two or more (such as three) thereof.

The radical polymerizable compounds are photoradical crosslinking agents, and not particularly limited to certain types. In a preferred embodiment of the present invention, the radical polymerizable compound is a compound having at least two (meth)acrylate groups, such as the compound having two (meth)acrylate groups, the compound having three (meth)acrylate groups, the compound having four (meth)acrylate groups, the compound having five (meth)acrylate groups, or the compound having six (meth)acrylate groups. Examples of the compound having at least two (meth)acrylate groups may include, but are not limited to, ethylene glycol dimethacrylate; EO modified diacrylate of bisphenol A (n=2 to 50) (EO being Ethylene oxide, and n being the molar number of ethylene oxide added); EO modified diacrylate of bisphenol F; BLEMMER PDE-100®, PDE-200®, PDE-400®, PDE-600®, PDP-400®, PDBE-200A®, PDBE-450A®, ADE-200®, ADE-300®, ADE-400A®, ADP-400® (NOF Co., Ltd.); Aronix M-210®, M-240® and/or M-6200® (manufactured by Toagosei Synthetic Chemical Co., Ltd.); KAYARAD HDDA®, HX-220®, R-604® and/or R-684® (Nippon Kayaku Co., Ltd.); V-260®, V-312® and/or V-335HP® (Osaka Organic Chemical Ind., Ltd.); trimethylolpropanetriacrylate (TMPTA); methylolpropanetetraacrylate; glycerinepropoxylatetriacrylate; triethoxytrimethylolpropanetriacrylate; trimethylolpropanetrimethacrylate; tris(2-hydroxyethyl)isocyanate triacrylate (THEICTA); pentaerythritoltroacrylate; pentaerythritolhexaacrylate; Aronix M-309®, M-400®, M-405®, M-450®, M-710®, M-8030® and/or M-8060® (Toagosei Synthetic Chemical Co., Ltd.); KAYARAD DPHA®, TMPTA®, DPCA-20®, DPCA-30®, DPCA-60® and/or DPCA-120® (Nippon Chemical Co., Ltd.); V-295®, V-300®, V-360®, V-GPT®, V-3PA® and/or V-400® (Osaka Yuki Kayaku Kogyo Co., Ltd).

In another preferred embodiment of the present invention, the radical polymerizable compound is a polyamic acid ester having a (meth)acrylate group, i.e. a polyamic acid ester having a (meth)acrylate group (CH₂=C(CH₃)—COO—) or a polyamic acid ester having an acrylate group (CH₂=CH—COO—). In a preferred embodiment, the polyamic acid ester having a (meth)acrylate group is obtained by reacting tetracarboxylic dianhydride, 2-hydroxyethyl methacrylate, and a diamine.

In the consideration of obtaining a proper polymerizability, the content of the radical polymerizable compound of the photosensitive polyimide resin is preferably between 1 to 50% by mass based on the total solid content of the photosensitive polyimide resin composition. The lower limit is more preferably raised up to 5% by mass or more. The upper limit is more preferably lower down to 40% by mass or less. The resin composite might contain single type of radical polymerizable compound or combine two or more types (for example, two, three, or four) thereof. Preferably, three kinds of the radical polymerizable compound are mixed for use and, more preferably, at least one of the three kinds of the radical polymerizable compound is the polyamic acid ester having the (meth)acrylate group.

In the present invention, the content of the polyamic acid ester having the (meth)acrylate group in the radical polymerizable compound is preferably ranged from 10 to 98 wt %, more preferably ranged from 30 to 95 wt %, particularly preferably ranged from 50 to 90 wt %. When the content of the polyamic acid ester having the (meth)acrylate group is within the above range, a cured film having more excellent curability can be formed. The resin composite might contain single type of radical polymerizable compound or combine with two or more thereof. When two or more are used, it is preferable that the total amount of the radical polymerizable compounds is within the above range.

When the content of the radical polymerizable compound is within the above range, the cross-linking bond produced by the radical reaction initiated by the photo radical initiator and the UV radiation can improve the pattern forming ability. In addition, curing by exposure can be sufficiently achieved during pattern formation, and the contrast of the alkaline developer can be improved.

In the present invention, the solvent is not particularly limited as long as it can dissolve the photosensitive polyimide. Examples of the solvent include, but are not limited to, ethyl acetate, n-butyl acetate, γ-butyrolactone, ε-caprolactone, diethylene glycol dimethyl ether, tetrahydrofuran, ethylene glycol monomethyl ether, ethylene glycol monoethyl ether, diethylene glycol monomethyl ether, diethylene glycol monoethyl ether, diethylene glycol monobutyl ether, propylene glycol monomethyl ether, propylene glycol monomethyl ether acetate, propylene glycol monoethyl ether acetate, and propylene glycol monopropyl ether acetate, methyl ethyl ketone, cyclohexanone, cyclopentanone, N-methylpyrrolidone, dimethylformamide, dimethyl sulfoxide or N,N-dimethylacetamide (DMAc). The solvent system may contain single solvent or more (such as two, three or four) thereof. In consideration of improving the state of the coated surface, it is preferred to mix two or more solvents for use. From the viewpoint of the coating—ability, the content of the solvent with respect to resin composition is preferably between 5 to 80% by mass, more preferably between 5 to 70% by mass, and particularly preferably between 10 to 60% by mass. One or two or more kinds of solvent maybe used. When two or more kinds of solvent are used, it is preferable that the total amount of the solvents is within the above range.

Additives may apply to the photosensitive polyimide resin composition. The selection of the additives may depend on the application of the photosensitive polyimide resin composition of the present invention. Examples of the additive include, but are not limited to, higher fatty acid derivatives, surfactants, inorganic particles, curing agent, curing catalysts, fillers, antioxidants, ultraviolet absorbers, anticoagulants, leveling agents or a combination of two or more thereof. When preparing resin which contains the additives, the total amount of the additives is preferably equal to 10% by mass or less with respect to the solid content of the photosensitive polyimide resin composition.

The present invention also provides a polyimide film formed from the resin composition described above.

In a preferred embodiment, the polyimide film has a total light transmittance over 90% at a wavelength between 400 and 700 nm and a yellowness of less than 2.

In a preferred embodiment, the polyimide film has a transmittance of more than 85% at a wavelength between 400 and 700 nm after a thermal-resist test at 260° C. for 10 minutes and a ΔE of less than 2.0.

The interlayer insulating film and the protective film of the present invention can be prepared by spin coating or cast coating, which coats a substrate with the photosensitive polyimide resin composition, followed by prebaking to remove the solvent and then form a pre-baked film. The optimal prebaking conditions depend on the resin formulation, and are usually at 80 to 120° C. for 5 to 15 min. After prebaking, the coated film is exposed to specific light sources under masks, where the light sources are preferably ultraviolet of g-line, h-line, line etc. The ultraviolet irradiation device may be (ultra) high-pressure mercury lamp and metal halogen lamp. Then, the exposed film is immersed in a developing solution at a temperature of 20 to 40° C. for 1 to 2 min to remove the unnecessary portions and form a specific pattern. Examples of the developer include, but are not limited to, methanol, ethanol, propanol, isopropanol, butanol, ethyl acetate, n-butyl acetate, γ-butyrolactone, ε-caprolactone, diethylene glycol dimethyl ether, tetrahydrofuran, ethylene glycol monomethyl ether, ethylene glycol monoethyl ether, diethylene glycol monomethyl ether, diethylene glycol monoethyl ether, diethylene glycol monobutyl ether, propylene glycol monomethyl ether, propylene glycol monomethyl ether acetate, propylene glycol monoethyl ether acetate, propylene glycol monopropyl ether acetate, methyl ethyl ketone, cyclohexanone, cyclopentanone, N-methyl pyrrolidone, dimethylformamide, dimethyl sulfoxide or N,N-dimethylacetamide. The developer may also be a combination of two or more of the above organic solvents.

When a developer composed of the above organic solvents is used, an organic solvent is usually used for washing after development, followed by air-drying with compressed air or compressed nitrogen. Next, post-baking treatment is performed using a heating device such as a hot plate or an oven, and the temperature of the post-baking treatment is usually between 180 to 250° C. After the above processing steps, a protective film can be formed.

Accordingly, the present invention further provides a substrate comprising the aforementioned polyimide film.

The photosensitive polyimide resin composition of the present invention has advantages of low curing temperature, high film thickness retention ratio, low residual film ratio of development, excellent flatness, easily forming fine pattern, high sensitivity, high transmittance, and good adhesion. The photosensitive polyimide resin composition of the present invention can be further used as a planarization layer or a passivation film in a thin film transistor liquid crystal display (TFT-LCD), a protective layer or an insulating layer in a touch panel device, or one the transparent printed circuit board.

To highlight the efficacy of the present invention, the inventors have completed the examples and comparative examples in the manners set forth below. The following examples and comparative examples are experimental data of the inventors and do not fall in the scope of the prior art. The following examples and comparative examples are intended to further illustrate the present invention, but not intended to limit the scope of the invention. Any changes and modifications made by those skilled in the art without departing from the spirit of the invention are within the scope of the invention.

### Synthesis Example 1: Preparation of Photosensitive Polyimide

62.12 g (0.194 mole) of 2,2′-bis(trifluoromethyl)benzidine (TFMB) and 500 g of DMAc were placed in a three-necked flask. After stirring at 30° C. till complete dissolution, 84.86 g (0.200 mole) of propylene glycol bis(trimellitic anhydride) (TMPG) was added, followed by continuous stirring and reaction at 25° C. for 24 hours to obtain a polyamic acid solution. Then, 23.00 g (0.290 mole) of pyridine and 59.4 g (0.582 mole) of acetic anhydride were further added, followed by continuous stirring and reaction at 25° C. for 24 hours. After the reaction is completed, polyimide was precipitated in 5 liters of water, and the mixture of water and polyimide was stirred at 5000 rpm for 15 minutes. The polyimide was obtained after filtration, and then poured again into 4 liters of water, stirred for 30 minutes, and subjected to filtration again. Thereafter, the obtained polyimide was dried at 45° C. for 3 days under reduced pressure to obtain dried polyimide (TMPG-TFMB PI (A1)). The test results of the resulted A1 by ¹H-NMR are shown below (the ratio of hydrogen number is defined by the non-repeating structure unit). ¹H-NMR (500 MHz, DMSO-de, δ ppm) 8.47-8.20 (4H, m), 8.15-7.70 (6H, m), 7.47-7.41 (2H, m), 4.45-4.38 (4H, m), 2.48-2.39 (2H, m); FT-IR (cm⁻¹) 3066, 2971, 1785, 1722, 1605, 1490, 1431, 1315, 1278, 1145, 840, 722.

### Synthesis Example 2: Preparation of Polyamic Acid Ester Having Methacrylate Group

### Synthesis of Polyamic Acid Ester Having an Acrylate Group (D3) by Propylene Glycol bis(trimellitic anhydride) (TMPG), 2,2′-bis(trifluoromethyl)benzidine (TFMB), and 2-hydroxyethyl methacrylate (HEMA)

In a four-necked flask, 16.97 g (40.0 mmol) of propylene glycol bis(trimellitic anhydride) (TMPG), 10.94 g (84.0 mmol) of 2-hydroxyethyl methacrylate (HEMA), 0.04 g (0.4 mmol) of hydroquinone, 3.16 g (84.0 mmol) of pyridine, and 80 mL of tetrahydrofuran were added sequentially and stirred at 50° C. for 3 hours, and a clear solution was obtained after a few minutes from the start of heating. The reaction mixture was cooled to room temperature, and then cooled to −10° C. While maintaining the temperature at −10±4° C., 11.9 g (100.0 mmol) of thionyl chloride was added over 10 minutes. The viscosity increases during the addition of thionyl chloride. After dilution with 50 mL of dimethylacetamide, the reaction mixture was stirred at room temperature for 2 hours. The temperature was kept at −10±4° C., and 11.62 g (200.0 mmol) of propylene oxide as a neutralizing agent was used to neutralize excess hydrochloric acid. A solution of 12.75 g (39.8 mmol) of 2,2′-bis(trifluoromethyl)benzidine (TFMB) dissolved in 100 mL of dimethylacetamide was added dropwise into the reaction mixture in 20 minutes, and the reaction mixture was stirred at room temperature for 15 hours. After the reaction is completed, the polyamic acid ester having the methacrylate group was precipitated in 5 liters of water, and the mixture of water and the polyamic acid ester having the methacrylate group was stirred at 5000 rpm for 15 minutes. The polyamic acid ester having the methacrylate group was obtained after filtration, and then poured again into 4 liters of water, stirred for 30 minutes, and subjected to filtration again. Thereafter, the obtained polyamic acid ester having the methacrylate group was dried at 45° C. for 3 days under reduced pressure to obtain dried polyamic acid ester having the methacrylate group (HEMA-TMPG-TFMB PAE (D3)). The test results of the resulted D3 ¹H-NMR are shown below (the ratio of hydrogen number is defined by the non-repeating structure unit). ¹H-NMR (500 MHz, DMSO-de, δ ppm) 11.10-11.07 (2H, m, NH), 8.46-8.43 (2H, m), 8.39-8.32 (2H, m), 8.12-8.01 (2H, m), 7.60-7.38 (4H, m), 7.30-7.23 (2H, m), 4.49-4.30 (12H, m), 2.49-2.40 (2H, m), 1.84-1.80 (6H, m); FT-IR (cm⁻¹) 2923, 2821 (C—H), 1780 (C═O), 1725 (C═O), 1648 (CH₂=CH), 1615, 1485, 1425, 1366, 1273, 1241, 1198, 1134, 1078, 842, 742.

### Examples 1-8 and Comparative Examples 1-3: Preparation of Photosensitive Polyimide Resin Compositions

The components used in the photosensitive polyimide resin composition are as follows. The components listed below were mixed with a solvent in a weight ratio as shown in Table 1 to prepare a solution having a solid content of 30%, which is a coating solution of a photosensitive polyimide resin composition.

Component A1: TMPG-TFMB PI

Component B1: SiO₂ having a particle diameter of 20 nm

Component B2: Al₂O₃ having a particle diameter of 20 nm

Component B3: SiO₂ having a particle diameter of 0.2 μm

Component B4: SiO₂ having a particle diameter of 1.0 μm

Component Cl: Irgacure 184

Component D1: Polydipentaerythritolhexaacrylate (DPHA)

Component D2: PDBE-450A (NOF)

Component D3: HEMA-TMPG-TFMB PAE

Component E1: DMAc

Evaluation Results

<Pattern Formability>

The photosensitive resin composition was coated on a copper foil substrate, and then dried at 90° C. for 5 minutes to obtain a surface-driedfilm of 15 μm. After exposure through a photomask, the exposed layer of the photosensitive polyimide resin composition was developed for 60 seconds by using cyclopentanone. Whether the line width of the formed pattern has good edge sharpness or not was evaluated by the following criteria. The smaller the line width of the photosensitive polyimide resin composition layer, the larger the difference in solubility of the light-irradiated portion and the non-light-irradiated portion with respect to the developer, resulting in preferable outcome. Further, the smaller the change in the line width with respect to the change in the exposure energy, the wider the exposure tolerance, which is a preferable result.

After observing the formed adhesive pattern by an optical microscope, the case where a thin line pattern having a line width/pitch width of 50 μm/50 μm or less was set to A, and the case where a thin line pattern having a line width/pitch width of more than 50 μm/50 μm was set to B to evaluate the pattern formability. The evaluation results are shown in Table 1.

<Total Light Transmittance>

The light transmittance of the polyimide film formed from the photosensitive polyimide resin composition at a wavelength of 400 to 700 nm was measured by using a HAZE Meter NDH4000 (manufactured by Nippon Denshoku Industries Co., Ltd.), and the lowest value obtained is taken as the transmittance.

<Yellowness>

The polyimide film formed from the photosensitive polyimide resin composition was measured for b value in the (L, a, b) color system using a spectrophotometer CM-600d (manufactured by Konica Minolta Sensing Co., Ltd.).

<Heat Test>

After the polyimide film formed from the photosensitive polyimide resin composition was baked at 260° C. for 10 minutes, the light transmittance of the polyimide film at a wavelength of 400 to 700 nm was measured by using a HAZE Meter NDH4000 (manufactured by Nippon Denshoku Industries Co., Ltd.).

The formulations of the photosensitive polyimide resin compositions of Examples 1 to 8 and Comparative Examples 1 to 3 as well as the test results of the polyimide films formed therefrom are shown in Table 1.

TABLE 1

| | | | | | | | | | | | Comparative | | |
|---|---|---|---|---|---|---|---|---|---|---|---|---|---|
| | | | Example | | | | | | | | Example | | |
| | | | 1 | 2 | 3 | 4 | 5 | 6 | 7 | 8 | 1 | 2 | 3 |
| Formulation | Photosensitive | A1 | 50 | 40 | 30 | 20 | 10 | 30 | 30 | 30 | 60 | 10 | 30 |
| | polyimide | | | | | | | | | | | | |
| | Filler | B1 | 10 | 20 | 30 | 40 | 50 | | | 20 | | 60 | |
| | | B2 | | | | | | 30 | | | | | |
| | | B3 | | | | | | | 30 | 10 | | | |
| | | B4 | | | | | | | | | | | 30 |
| | Photo radical | C1 | 5 | 5 | 5 | 5 | 5 | 5 | 5 | 5 | 5 | 5 | 5 |
| | initiator | | | | | | | | | | | | |
| | Crosslinking | D1 | 5 | 5 | 5 | 5 | 5 | 5 | 5 | 5 | 5 | 5 | 5 |
| | agent | D2 | 10 | 10 | 10 | 10 | 10 | 10 | 10 | 10 | 10 | 10 | 10 |
| | | D3 | 20 | 20 | 20 | 20 | 20 | 20 | 20 | 20 | 20 | 10 | 20 |

| | | | | | | | | | | | | |
|---|---|---|---|---|---|---|---|---|---|---|---|---|
| Evaluation | Resolution | A | A | A | A | A | A | A | A | B | B | B |
| results | Transmittance | 90 | 91 | 95 | 93 | 92 | 93 | 95 | 93 | 82 | 90 | 88 |
| | (T %) | | | | | | | | | | | |
| | T % after thermal- | 85 | 86 | 89 | 88 | 86 | 89 | 90 | 88 | 78 | 84 | 82 |
| | resist test *1 | | | | | | | | | | | |
| | Yellowness | 1.9 | 1.8 | 1.5 | 1.2 | 1.1 | 1.6 | 1.9 | 1.2 | 3.0 | 1.3 | 2.8 |
| | (b value) | | | | | | | | | | | |
| | ΔE after thermal- | 1.9 | 1.9 | 1.6 | 1.4 | 1.3 | 1.5 | 1.4 | 1.6 | 2.5 | 1.5 | 2.3 |
| | resist test *2 | | | | | | | | | | | |

Note 1:
The unit of the components in Table 1 is part by weight.
Note 2:
If the yellowness is higher than 2.0, it will be visible.

As shown in Table 1, the photosensitive polyimide resin composition of the present invention has excellent performance in yellowness, transmittance, resolution, and heat resistance, and has good transparency, particularly in Example 3. In contrast, the composition of Comparative Example 1 in which no filler was added exhibited poor performance in resolution, yellowness, transmittance, and heat resistance. The composition of Comparative Example 2 in which high proportion filler was added has difficulty in development and thus poor resolution due to the addition of high proportion filler to the film. The composition of Comparative Example 3 used the filler having a relatively large particle diameter, so the film exhibited severely atomized phenomenon after drying, resulting in poor performance of total light transmittance.

In summary, the photosensitive polyimide resin composition of the present invention can form the polyimide film having both high transmittance and low thermal yellowing. Since the polyimide film of the present invention has a low yellowness value, it has good transparency.

Those described above are only the preferred embodiments of the present invention, and are not intended to limit the scope of the present invention. All the simple and equivalent variations and modifications made according to the claims and the description of the present invention are still within the scope of the present invention.

1. A photosensitive polyimide resin composition, comprising (a) a photosensitive polyimide represented by formula (1); (b) a filler selected from the group consisting of alumina, graphene, inorganic clay, silica, zinc oxide, and combinations thereof and having a particle diameter ranging from 10 nm to 1.0 μm; (c) a photo radical initiator; (d) a radical polymerizable compound; and (e) a solvent for dissolving the photosensitive polyimide; 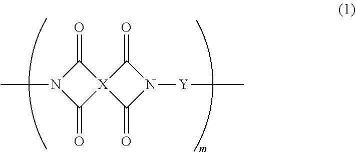
wherein X is derived from a tetracarboxylic dianhydride, Y is derived from a diamine, and m is a positive integer from 1 to 5000.

2. The resin composition according to claim 1, wherein the tetracarboxylic dianhydride is selected from the group consisting of 3,3′,4,4′-biphenyltetracarboxylic dianhydride, 3,3′,4,4′-benzophenone tetracarboxylicdianhydride, 4,4′-oxydiphthalic anhydride, bis(3,4-dicarboxyphenyl)methane dianhydride, 2,2-di(3,4-dicarboxyphenyl)propane dianhydride, 2,2-bis(3,4-dicarboxyphenyl)propane dianhydride, 1,3-bis(3,4-dicarboxyphenoxy)benzenedianhydride, 1,4-bis(3,4-dicarboxyphenoxy)benzenedianhydride, 4,4′-bis(3,4-dicarboxyphenoxy)biphenyl dianhydride, 2,2-bis[4-(3,4-dicarboxyphenoxy)phenyl]propane dianhydride, ethylene glycol bis(trimellitic anhydride) (TMEG), propylene glycol bis(trimellitic anhydride) (TMPG), 1,2-propanediol bis(trimellitic anhydride), butanediolbis(trimellitic anhydride), 2-methyl-1,3-propanediol bis(trimellitic anhydride), dipropylene glycol bis(trimelliticanhydride), 2-methyl-2,4-pentanediol bis(trimellitic anhydride), diethylene glycol bis(trimellitic anhydride), tetraethylene glycol bis(trimellitic anhydride), hexaethylene glycol bis(trimellitic anhydride), neopentyl glycol bis(trimellitic anhydride), hydroquinone bis(2-hydroxyethyl)ether bis(trimellitic anhydride), 2-phenyl-5-(2,4-xylyl)-1,4-hydroquinone bis(trimellitic anhydride), 2,3-dicyanohydroquinone cyclobutane-1,2,3,4-tetracarboxylic dianhydride, 1,2,3,4-cyclopentanetetracarboxylic dianhydride, 1,2,4,5-cyclohexane tetracarboxylicdianhydride, bicyclo[2.2.1]heptane-2,3,5,6-tetracarboxylic dianhydride, bicyclo[2.2.2]oct-7-ene-2,3,5,6-tetracarboxylic dianhydride, bicyclo[2.2.2]octane-2,3,5,6-tetracarboxylic dianhydride, 2,3,5-tricarboxy-cyclopentyl acetic dianhydride, bicyclo[2.2.1]heptane-2,3,5-tricarboxy-6-acetic dianhydride, decahydro-1,4,5,8-dimethanonaphthalene-2,3,6,7-tetracarboxylic dianhydride, butane-1,2,3,4-tetracarboxylic dianhydride, 3,3′,4,4′-dicyclohexyltetracarboxylic dianhydride, and combinations thereof.

3. The resin composition according to claim 1, wherein the diamine is selected from the group consisting of 3,3′-diaminodiphenyl sulfone, 4,4′-diaminodiphenyl sulfone, 3,3′-methylenediphenylamine, 4,4′-methylenediphenylamine, 2,2-bis(4-aminophenyl)propane, 2,2-bis(4-aminophenyl)hexafluoropropane, 2,2′-bis(trifluoromethyl)benzidine, 2,2′-dimethylbenzidine, 3,3′-dihydroxybenzidine, 1,3-bis(3-aminophenoxy)benzene, 1,3-bis(4-aminophenoxy)benzene, 1,4-bis(4-aminophenoxy)benzene, 4,4′-bis(4-aminophenoxy)biphenyl, 2,2-bis[4-(4-aminophenoxy)phenyl]propane, 2,2-bis[4-(4-aminophenoxy)phenyl]-1,1,1,3,3,3-hexafluoropropane, 1,3-bis[4-(3-aminophenoxy)benzoyl]benzene, 4,4′-diaminobenzanilide, 2,2-bis(3-amino-4-hydroxyphenyl)hexafluoropropane, 5-amino-2-(p-aminophenyl)benzoxazole, 6-amino-2-(p-aminophenyl)benzoxazole, and combinations thereof.

4. The resin composition according to claim 1, wherein the particle diameter of the filler ranges from 20 nm to 0.2 μm.

5. The resin composition according to claim 1, wherein the filler accounts for 10% to 50% by weight of a solid content of the photosensitive polyimide resin composition.

6. The resin composition according to claim 5, wherein the filler accounts for 20% to 40% by weight of a solid content of the photosensitive polyimide resin composition.

7. The resin composition according to claim 1, wherein the radical polymerizable compound is a compound having at least two (meth)acrylate groups.

8. The resin composition according to claim 1, wherein the radical polymerizable compound is a polyamic acid ester having the (meth)acrylate group.

9. The resin composition according to claim 8, wherein a content of the polyamic acid ester having the (meth)acrylate group in the radical polymerizable compound is from 10% to 98% by weight.

10. The resin composition according to claim 1, wherein a polyimide film formed therefrom has a transmittance of more than 90% at a wavelength from 400 nm to 700 nm and a yellowness of less than 2.

11. A polyimide film formed from the resin composition according to claim 1.

12. The polyimide film according to claim 11, having a transmittance of more than 90% at a wavelength from 400 nm to 700 nm and a yellowness of less than 2.

13. The polyimide film according to claim 11, having a transmittance of more than 85% at a wavelength from 400 nm to 700 nm after a heat test at 260° C. for 10 minutes and a ΔE of less than 2.0.

14. A substrate comprising the polyimide film according to claim 11.
